(19) United States
(12) Patent Application Publication
(10) Pub. No.: US 2025/0233006 A1
(43) Pub. Date: Jul. 17, 2025

(54) APPARTUS FOR DETECTING POSITION OF WAFER AND OPERATING METHOD THEREOF

(71) Applicant: Samsung Electronics Co., Ltd., Suwon-si (KR)

(72) Inventors: Kyungrim Kim, Suwon-si (KR); Ohhyuk Kwon, Suwon-si (KR); Iksu Byun, Suwon-si (KR)

(21) Appl. No.: 18/813,063

(22) Filed: Aug. 23, 2024

(30) Foreign Application Priority Data
Jan. 16, 2024 (KR) 10-2024-0006405
Apr. 24, 2024 (KR) 10-2024-0054906

(51) Int. Cl. H01L 21/687; G01H 11/08; H01L 21/67

(52) U.S. Cl. CPC H01L 21/68742; G01H 11/08; H01L 21/67259

(57) ABSTRACT

An apparatus for detecting a position of a wafer includes a plurality of lift pins disposing the wafer on a support stand and a plurality of piezoelectric resonators at lower portions of the plurality of lift pins, respectively, wherein at least one first piezoelectric resonator among the plurality of piezoelectric resonators is configured to vibrate a corresponding lift pin of the plurality of lift pins, at least one second piezoelectric resonator among the plurality of piezoelectric resonators is configured to detect a resonant frequency of a combined structure including the wafer and the plurality of lift pins, the resonant frequency corresponding to the vibration, and the apparatus further includes a controller configured to determine the position of the wafer according to a change in the resonant frequency.

### CROSS-REFERENCE TO RELATED APPLICATIONS

This application claims benefit of priority to Korean Patent Application Nos. 10-2024-0006405 filed on Jan. 16, 2024 and 10-2024-0054906 filed on Apr. 24, 2024 in the Korean Intellectual Property Office, the disclosures of which are incorporated herein by reference in its entirety.

### BACKGROUND

Aspects of the present inventive concept relate to an apparatus for detecting a position of a wafer and an operating method thereof.

Generally, in semiconductor processes, the importance of technology that can detect the real-time position of wafers is increasing to control process variation and prevent issues such as wafer sliding or breakage. Due to various environmental constraints, there is currently no effective method to measure the position of wafers. These environmental constraints include narrow physical spaces for displacement sensors, process impact when sensors are exposed to the process, and performance degradation in high-temperature and plasma environments. As an alternative, one method involves using an Auto Wafer Centering Sensor (AWC) to indirectly predict the wafer position by comparing its location when it enters and exits the chamber. However, this method does not allow for real-time position monitoring, making it difficult to prevent issues related to wafer position in advance. Additionally, in structures like quad-type chambers composed of multiple stations, it is impossible to accurately measure position changes using only AWC.

### SUMMARY

An aspect of the present inventive concept is to provide an apparatus for detecting a position of a wafer and an operating method thereof, capable of detecting a position of a wafer in a processing chamber in real time.

According to an aspect of the present inventive concept, an apparatus for detecting a position of a wafer includes: a plurality of lift pins configured to seat the wafer on a support stand; and a plurality of piezoelectric resonators at lower portions of the plurality of lift pins, respectively, wherein at least one first piezoelectric resonator among the plurality of piezoelectric resonators is configured to vibrate a corresponding lift pin of the plurality of lift pins, wherein at least one second piezoelectric resonator among the plurality of piezoelectric resonators is configured to detect a resonant frequency of a combined structure including the wafer and the plurality of lift pins, the resonant frequency corresponding to the vibration, and wherein the apparatus further comprises a controller configured to determine the position of the wafer according to a change in the resonant frequency.

According to an aspect of the present inventive concept, an apparatus for detecting a position of a wafer includes: a plurality of piezoelectric resonators; and a controller configured to receive an electrical signal, the electrical signal corresponding to a resonant frequency of a combined structure including the wafer and a plurality of lift pins, from at least one of the plurality of piezoelectric resonators and determine the position of the wafer according to the received electrical signal.

According to an aspect of the present inventive concept, an apparatus for detecting a position of a wafer includes: a lift pin configured to move vertically within a hole of a support stand to seat the wafer on the support stand; a connection assembly connected to a lower portion of the lift pin; a piezoelectric resonator at a lower portion of the connection assembly, the piezoelectric resonator being configured to detect a resonant frequency of the lift pin; an actuator configured to move the lift pin vertically; and a controller configured to control the actuator, wherein the controller is configured to receive an electrical signal corresponding to the resonant frequency from the piezoelectric resonator and determine the position of the wafer according to the electrical signal.

According to an aspect of the present inventive concept, an operating method of an apparatus for detecting a position of a wafer includes: disposing a wafer on a support stand via lift pins; detecting a resonant frequency of a wafer-lift pin structure using a piezoelectric resonator; and measuring a position of the wafer using the detected resonant frequency.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a diagram illustrating a substrate processing system according to an example embodiment of the present inventive concept;

FIG. 2 is a diagram illustrating a semiconductor manufacturing apparatus according to an example embodiment of the present inventive concept;

FIG. 3 is a diagram illustrating a semiconductor manufacturing device performing a general automatic wafer centering function;

FIG. 4 is a diagram illustrating an apparatus for detecting a position of a wafer according to an example embodiment of the present inventive concept;

FIGS. 5A and 5B are diagrams illustrating wafer position deviation in an apparatus for detecting a position of a wafer according to an example embodiment of the present inventive concept;

FIGS. 6A, 6B, and 6C are diagrams illustrating predicting a position of a wafer by measuring a resonant frequency in an apparatus for detecting a position of a wafer according to an example embodiment of the present inventive concept;

FIGS. 7A and 7B are diagrams illustrating resonant frequency measurement results according to a wafer position in an apparatus for detecting a position of a wafer according to an example embodiment of the present inventive concept;

FIG. 8 is a diagram illustrating a resonant frequency according to the degree to which the wafer is deviated from the center in the apparatus for detecting a position of a wafer according to an example embodiment of the present inventive concept;

FIGS. 9A, 9B, and 9C are diagrams illustrating a lift pin assembly according to an example embodiment of the present inventive concept;

FIGS. 10A and 10B are diagrams illustrating an apparatus for detecting a position of a wafer; and

FIG. 11 is a flowchart illustrating a wafer position detection operation of a semiconductor manufacturing apparatus according to an example embodiment of the present inventive concept.

### DETAILED DESCRIPTION

Hereinafter, example embodiments of the present inventive concept will be described with reference to the accompanying drawings.

A wafer position detection device and operating method thereof according to the embodiment of the present invention may detect the position of a wafer placed on a lift pin inside a chamber in real-time using a piezoelectric resonator. The wafer position detection device of the present invention is capable of real-time measurement of the wafer position on the lift pin. Since the sensor of the wafer position detection device of the present invention is attached outside the process space (for example, below the lift pin), it does not affect the process. The wafer position detection device of the present invention can precisely measure the position of the wafer (expected sensitivity: approximately 0.5 mm/Hz). The wafer position detection device of the present invention may precisely measure the wafer position inside the chamber in real-time.

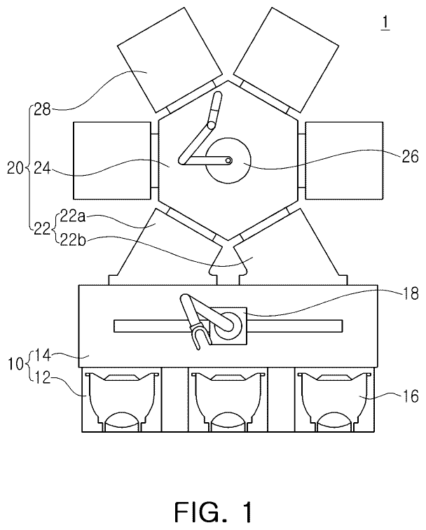

FIG. 1 is a diagram illustrating a substrate processing system 1 according to an example embodiment of the present inventive concept. Referring to FIG. 1, the substrate processing system 1 may include an equipment front end module 10 and process equipment 20. The equipment front end module 10 may be mounted at the front of the process equipment 20. The equipment front end module 10 may transfer a substrate between a container 16 in which substrates are accommodated and the process equipment 20. The equipment front end module 10 may include a plurality of load ports 12 and a frame 14. The frame 14 may be disposed between the load port 12 and the process equipment 20.

The container 16 accommodating the substrate may be installed on the load port 12 by a transfer unit, such as an overhead transfer, overhead conveyor, or automatic guided vehicle. The container 16 may be an airtight container, such as a front open unified pod. A frame robot 18 transferring the substrate between the container 16 disposed in the load port 12 and the process equipment 20 may be disposed within the frame 14. A door opener automatically opening and closing a door of the container 16 may be installed within the frame 14. In addition, the frame 14 may include a fan filter unit supplying clean air to the frame 14 so that the clean air flows from the top to the bottom within the frame 14.

The process equipment 20 may include a load-lock chamber 22, a transfer chamber 24, and a processing chamber 28. The transfer chamber 24 has a substantially polygonal shape when viewed from above. The load-lock chamber 22 and/or the processing chamber 28 may be disposed on the side of the transfer chamber 24.

The load-lock chamber 22 may be interposed between the transfer chamber 24 and the equipment front end module 10. At least one load-lock chamber 22 may be provided. According to an example, two load-lock chambers 22 may be provided. Among the two load-lock chambers 22, substrates introduced into the process equipment 20 may be received in the first load-lock chamber 22a. Among the two load-lock chambers 22, substrates on which the process is completed and which are discharged from the process equipment 20 may be received in the second load-lock chamber 22b. Alternatively, one or more load-lock chambers 22 may be provided, and the substrate may be loaded to or unloaded from each load-lock chamber 22.

A transfer robot 26 may be mounted within the transfer chamber 24. The transfer robot 26 may load the substrate S to the processing chamber 28 or unload the substrate S from the processing chamber 28. In addition, the transfer robot 26 may transfer the substrate S between the processing chamber 28 and the load-lock chamber 22.

The inside of the transfer chamber 24 and the processing chamber 28 may be maintained at vacuum, and the inside of the load-lock chamber 22 may be converted between vacuum and atmospheric pressure. The load-lock chamber 22 may prevent external contaminants from entering the transfer chamber 24 and the processing chamber 28. A gate valve may be installed between the load-lock chamber 22 and the transfer chamber 24 and between the load-lock chamber 22 and the equipment front end module 10. The gate valve may open and close between the load-lock chamber 22 and the transfer chamber 24 and between the load-lock chamber 22 and the equipment front end module 10. For example, when a substrate is moved between the equipment front end module 10 and the load-lock chamber 22, the gate valve provided between the load-lock chamber 22 and the transfer chamber 24 may be closed. In addition, when the substrate is moved between the load-lock chamber 22 and the transfer chamber 24, the gate valve provided between the load-lock chamber 22 and the equipment front end module 10 may be closed.

The processing chamber 28 may be implemented to perform a predetermined process on the substrate. For example, the processing chamber 28 may perform processes, such as a deposition process, a development process, a cleaning process, or a curing process. One or a plurality of processing chambers 28 may be provided along the sides of the transfer chamber 24. When a plurality of processing chambers 28 are provided, each processing chamber 28 may perform the same process on the substrate or may perform different processes from each other on the substrate.

In addition, the processing chamber 28 may include an apparatus for detecting a position of a wafer in real time while performing the process. The apparatus for detecting a position of a wafer may detect the position of the wafer by measuring a resonant frequency corresponding to the substrate using a piezoelectric resonator and comparing the measured resonant frequency with an initial resonant frequency.

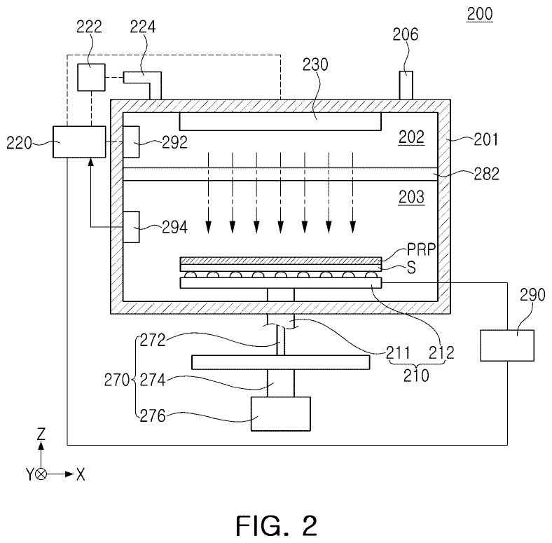

FIG. 2 is a diagram illustrating a semiconductor manufacturing apparatus 200 according to an example embodiment of the present inventive concept. Referring to FIG. 2, the semiconductor manufacturing apparatus 200 may include a chamber 201, a support device 210, a gas supply unit 222, a controller 220, a light source unit 230, and a lift pin assembly 270. Here, the semiconductor manufacturing apparatus 200 may perform a curing process on a photoresist pattern PRP coated on a substrate S. In an example embodiment, a process performed using the semiconductor manufacturing apparatus 200 may be a curing process.

The chamber 201 may have a cylindrical shape provided with an internal space within which a process is performed. The chamber 201 may be configured to isolate the space in which the process is performed from the outside. In addition, an exhaust pipe 206 discharging by-products occurring during the process may be connected to an outer surface of the chamber 201. The exhaust pipe 206 may include a pump maintaining the inside of the chamber 201 at a process pressure during the process and a valve opening and closing a passage within the exhaust pipe. The chamber 201 may include a transparent separator 282 disposed between the substrate S and the light source unit 230.

The transparent separator 282 may separate the chamber 201 into a first space 202 and a second space 203. The transparent separator 282 may allow light emitted from the light source unit 230 to be transmitted therethrough. That is, the transparent separator 282 may be formed of a transparent material allowing light to pass therethrough. For example, the transparent separator 282 may be formed of a quartz material, but is not limited thereto. The first space 202 may be an upper space within the chamber 201 and may be a space including the light source unit 230. The second space 203 may be a lower space within the chamber 201 and may be a space including the substrate S. The second space 203 may be a vacuum space. In addition, in a later process, a reaction gas may be introduced into the second space 203.

The support device 210 has a support plate 212 supporting the substrate S during the process. The support device 210 is substantially disk-shaped. A support shaft 211 rotatable by a driver 276 is fixedly coupled to a lower surface of the support plate 212. The substrate S may be rotated during the process. The support device 210 may fix the substrate using a method, such as electrostatic force or mechanical clamping.

The gas supply unit 222 may supply gas into the chamber 201. The gas supply unit 222 may supply gas into the chamber 201 through the gas supply pipe 224. In particular, the gas supply unit 222 may supply gas to the first space 202. Here, the supplied gas may be an inert gas. The inert gas may cool the first space 202. A valve opening and closing an internal passage may be installed in the gas supply pipe 224.

The controller 220 may adjust the amount and radiation time of light emitted from the light source unit 230. In addition, the controller 220 may receive a heating temperature of the substrate from a temperature controller. The controller 220 may receive a temperature of the first space 202 from a temperature sensor 292. When the temperature of the first space 202 exceeds a preset reference temperature, the controller 220 may control the gas supply unit 222 to supply gas to the first space 202.

Although not illustrated, a controller can include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the controller 220 (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the controller can include antennas, network interfaces that provide wireless and/or wire line digital and/or analog interface to one or more networks over one or more network connections (not shown), a power source that provides an appropriate alternating current (AC) or direct current (DC) to power one or more components of the controller, and a bus that allows communication among the various disclosed components of the controller.

The light source unit 230 may radiate light to the substrate S coated with a photoresist pattern PRP. The light source unit 230 may cure the photoresist pattern PRP by radiate light. The light source unit 230 may radiate UV light. The light source unit 230 may include a plurality of lamps. The light source unit 230 may include any one of a halogen lamp, a mercury lamp, a xenon lamp, and an LED lamp.

In an example embodiment, a wavelength of the light emitted by the light source unit 230 may be in the range of 200 nm to 800 nm. In an example embodiment, the wavelength of the light emitted by the light source unit 230 may be in the range of 300 nm to 700 nm.

The lift pin assembly 270 loads the substrate onto the support plate 212 or unloads the substrate from the support plate 212. The lift pin assembly 270 has a lift pin 272, a lift pin support plate 274, and the driver 276. The lift pin 272 is fixedly installed on the lift pin support plate 274 and moved together with the lift pin support plate 274. The lift pin support plate 274 has a disk shape and is located below the support plate 212 within the chamber 201 or outside the chamber 201. The lift pin support plate 274 is moved up and down by the driver 276, such as a hydraulic or pneumatic cylinder or a motor.

In addition, the lift pin assembly 270 may include at least one piezoelectric resonator generating a vibration signal or detecting a vibration signal.

The semiconductor manufacturing apparatus 200 may detect a position of the wafer in real time by detecting a resonant frequency using a piezoelectric resonator.

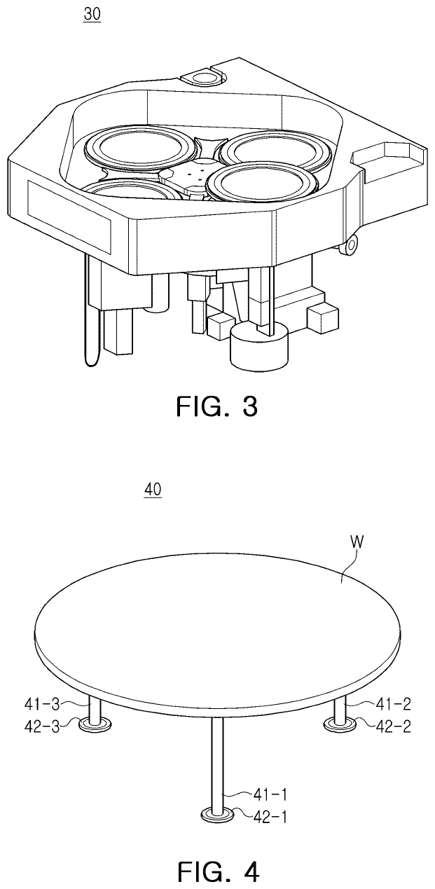

FIG. 3 is a diagram illustrating a semiconductor manufacturing device 30 performing a general automatic wafer centering function. The general semiconductor manufacturing device 30 may predict a position of the wafer or the amount of change in the wafer within the chamber by comparing wafer in/out positions through an automatic wafer centering (AWC) function.

A wafer position may be measured after the process is completed by comparing in/out coordinates. However, the apparatus for detecting a position of a wafer of the related art is unable to measure a wafer position in real time. In addition, it is impossible to detect a wafer position in a quad chamber in which the wafer moves within the chamber.

FIG. 4 is a diagram illustrating an apparatus 40 for detecting a position of a wafer according to an example embodiment of the present inventive concept. Referring to FIG. 4, the apparatus 40 for detecting a position of a wafer includes a plurality of lift pins 41-1, 41-2, and 41-3 and a plurality of piezoelectric resonators 42-1, 42-2, and 42-3.

The plurality of lift pins 41-1, 41-2, and 41-3 may be implemented to dispose the wafer W on a support stand. Each of the plurality of piezoelectric resonators 42-1, 42-2, and 42-3 may be disposed below the corresponding lift pins 41-1, 41-2, and 41-3, and may be disposed in connection portions of the lift pins 41-1, 41-2, and 41-3. For example, each of the lift pins 41-1, 41-2, and 41-3 may be disposed between the wafer and the corresponding piezoelectric resonator 42-1, 42-2, and 42-3. Each of the plurality of piezoelectric resonators 42-1, 42-2, and 42-3 may be implemented to generate vibration using a piezoelectric effect in each of the lift pins 41-1, 41-2, and 41-3. The piezoelectric effect refers to a phenomenon of generating an electrical signal by changing an internal charge distribution of a crystal by constant pressure or displacement. Using this effect, a piezoelectric resonator may convert mechanical energy into electrical energy. In addition, each of the plurality of piezoelectric resonators 42-1, 42-2, and 42-3 may be implemented to generate an electrical signal corresponding to each vibration of the lift pins 41-1, 41-2, and 41-3.

In an example embodiment, the first piezoelectric resonator 42-1 (also known as a ‘vibration generator’) may be implemented to generate vibrations. For example, the first piezoelectric resonator 41-1 may generate a vibration signal to finely move a structure (e.g., a combined structure including the lift pins and the wafer) in a specific frequency region. In an example embodiment, at least one of the second piezoelectric resonator 42-2 (in other words, ‘vibration detector’) and the third piezoelectric resonator 42-3 may be implemented to detect the resonant frequency by changing the vibration signal into an electrical signal. At this time, the position of the wafer may be measured based on a detected difference in resonant frequency.

In an example embodiment, each of the piezoelectric resonators 42-1, 42-2, and 42-3 may be implemented as a structure physically independent from the corresponding lift pin. For example, each of the piezoelectric resonators 42-1, 42-2, and 42-3 may not be integrated with but may instead by physically separable from the corresponding lift pin 41-1, 41-2, and 41-3.

Also, the apparatus 40 for detecting a position of a wafer of the present inventive concept may further include a controller receiving an electric signal from at least one second piezoelectric resonator and determining the position of the wafer according to the received electric signal.

Also, the number of lift pins shown in FIG. 4 is 3, and the number of piezoelectric resonators is also 3. However, it should be understood that the number of lift pins or the number of piezoelectric resonators of the present inventive concept is not limited thereto.

Also, the apparatus 40 for detecting a position of a wafer may detect the degree of positional deviation based on a change in resonant frequency according to the wafer position. In an example embodiment, the resonant frequency may vary according to the length, width, or material of each lift pin.

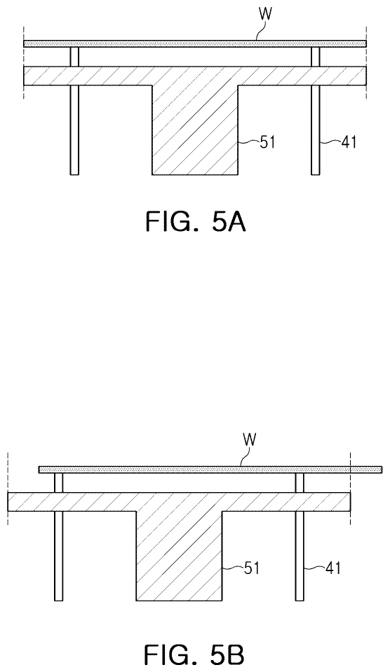

FIGS. 5A and 5B are diagrams illustrating wafer position deviation in an apparatus for detecting a position of a wafer according to an example embodiment of the present inventive concept. As shown in FIG. 5A, the wafer W may be disposed on the lift pins 41 above a support stand 51 in a wafer regular position. As shown in FIG. 5B, the wafer W may be disposed on the lift pins 41 above the support stand 51 in a wafer deviated position. Here, each of the lift pins 41 may be implemented to move up and down through the support stand 51.

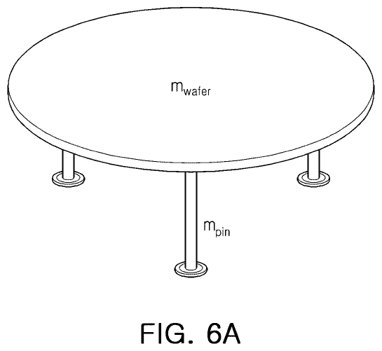

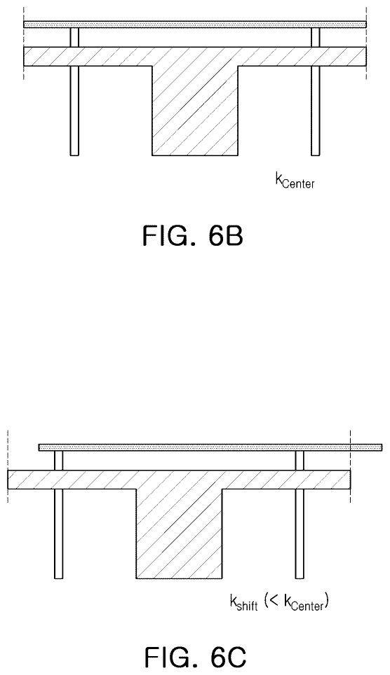

FIGS. 6A, 6B, and 6C are diagrams illustrating predicting a position of a wafer by measuring a resonant frequency in an apparatus for detecting a position of a wafer according to an example embodiment of the present inventive concept. As shown in FIG. 6A, the apparatus 40 for detecting a position of a wafer may be seen as a spring system (wafer-lift pin structure). Here, the mass of the wafer is m_{wafer} and the mass of the lift pins is mₚᵢₙ. As shown in FIG. 6B, when the wafer is located at the center, a spring constant is k_{center}. As shown in FIG. 6C, when the position of the wafer is deviated, the spring constant is k_{shift}.

The spring constant k of the structure system according to a change in position of the wafer disposed on the lift pin may change in accordance with a change in position of the wafer. Here, the lift pin and the wafer disposed on the lift pin may be assumed to be a single elastic body or mass-spring system. Generally, in the mass-spring system, the resonant frequency won is a function of the mass m and the spring constant k. The masses of the wafer and the lift pins are always the same, and the spring constant k may be determined by the system structure shape, such as the position of the wafer. Therefore, a change in the wafer position may be seen as a change in shape. The change in shape causes a change in spring constant. For example, k_{shift}<k_{center}. That is, m_{center}=m_{shift}=m_{wafer}+mₚᵢₙ.

Accordingly, the resonance frequencies ω_{n,center} and ω_{n,shift} according to the positions of the wafer satisfy the following equations, respectively.

$${ω}_{n . center} = \sqrt{\frac{{k}_{center}}{{m}_{wafer} + {m}_{pin}}} \neq {ω}_{n . shift} = \sqrt{\frac{{k}_{shift}}{{m}_{wafer} + {m}_{pin}}} \qquad [ Equation 1 ]$$

Here, ω_{n, center} is the resonant frequency at the wafer regular position, and k_{center} is the spring constant at the wafer regular position. m_{wafer} is the mass of the wafer, mₚᵢₙ is the mass of the lift pin, ω_{n, shift} and k_{center} are the resonant frequency and spring constant when the position of the wafer is deviated.

In Equation 1, ω=fk and k is a constant determined by the shape, that is, a relative position of the wafer. Therefore, the wafer position on the lift pins may be predicted by measuring the change in resonant frequency. That is, the apparatus for detecting a position of a wafer of the present inventive concept may measure the change in resonant frequency corresponding to the change in spring constant of the wafer-lift pin structure.

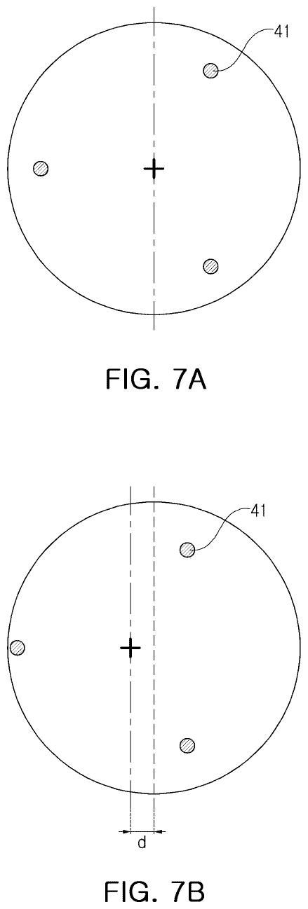

FIGS. 7A and 7B are diagrams illustrating resonant frequency measurement results according to a wafer position in an apparatus for detecting a position of a wafer according to an example embodiment of the present inventive concept. As shown in FIG. 7A, an initial wafer position may be centered. As shown in FIG. 7B, the position of the wafer that has moved by d (mm) may be deviated. When the wafer position changes, the resonant frequency value measured by the sensor may change according to a moving distance d. That is, the resonant frequency when the wafer is located at the center of the support stand and the resonant frequency when the wafer deviates from the center of the support stand may be different.

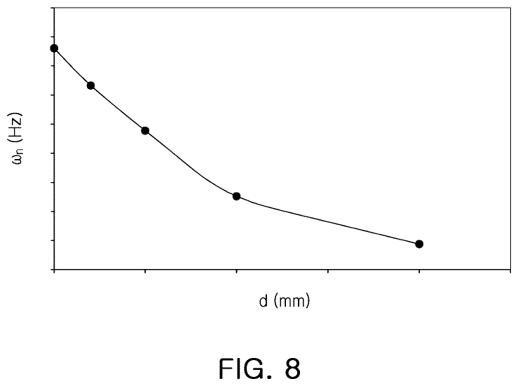

FIG. 8 is a diagram illustrating a resonant frequency according to the degree to which the wafer is deviated from the center in the apparatus for detecting a position of a wafer according to an example embodiment of the present inventive concept. Referring to FIG. 8, as the distance of the wafer away from the center increases, the resonant frequency measured by the sensor steadily decreases. Therefore, the wafer position may be precisely detected by the amount of change in the resonant frequency of the wafer-lift pin structure.

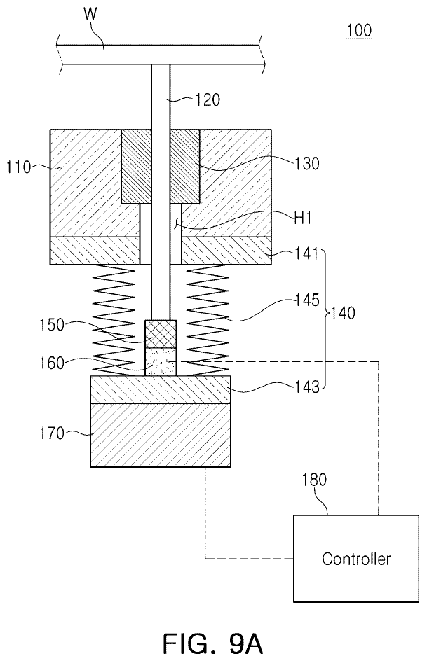

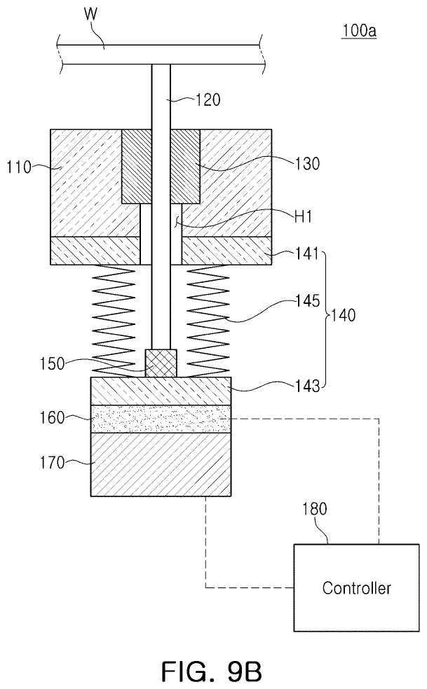

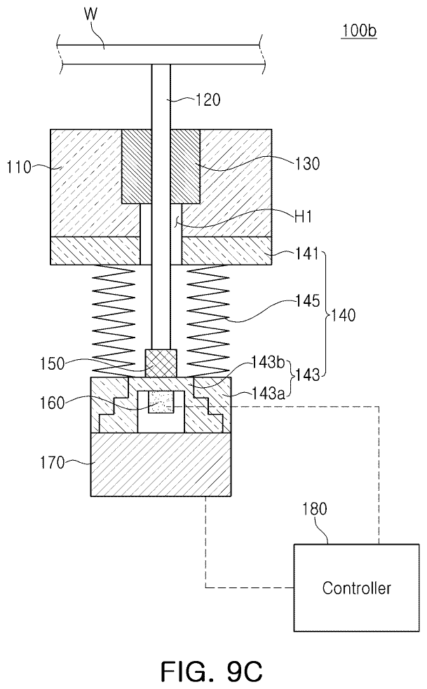

FIGS. 9A, 9B, and 9C are diagrams illustrating a lift pin assembly according to an example embodiment of the present inventive concept.

FIG. 9A is a diagram illustrating a lift device 100 according to an example embodiment of the present inventive concept. The lift device 100 may be a device configured to move the wafer W in a vertical direction in a substrate processing apparatus. In an example embodiment, the wafer W that the lift device 100 moves in the vertical direction may be a substrate including a wafer, a printed circuit board (PCB), or the like. The lift device 100 may move the substrate in the vertical direction to dispose and remove the substrate on an electrostatic chuck and to load the substrate into and out of the processing chamber.

In addition, the wafer W that the lift device 100 moves in the vertical direction may be a movable ring. A shape of plasma generated in a substrate processing process may change based on a vertical displacement of the moving ring. More specifically, if a portion of the moving ring is etched due to repetition of the substrate processing process and the shape of the plasma generated in the substrate processing process is different from a previously predicted shape, the lift device 100 may move the moving ring in the vertical direction. Accordingly, the plasma generated in the substrate processing process may be generated in the previously predicted shape.

The lift device 100 may include a body 110, a lift pin 120, a pin guide 130, a bellows 140, a connection assembly 150 (e.g., a connector), a piezoelectric resonator 160, an actuator 170, and a controller 180. The body 110 may be configured to support the wafer W described above. For example, the wafer W may be disposed on an upper surface of the body 110. In addition, a lift hole H1 may be formed in the body 110, and the lift hole H1 may overlap the wafer W in the vertical direction. In an example embodiment, the body 110 may be formed to surround an electrostatic chuck (not shown). The lift pin 120 may be configured to move the wafer W disposed on the body 110 in the vertical direction. More specifically, the lift pin 120 may be configured to move in the vertical direction within the lift hole H1 of the body 110 to move the wafer W in the vertical direction. In an example embodiment, the range of the resonant frequency of the wafer-lift pin structure may be determined according to the length, thickness, or material of the lift pin. The pin guide 130 may be located in the lift hole H1 of the body 110 and may be configured to guide the movement of the lift pin 120 in the vertical direction. An inner surface of the pin guide 130 may be spaced apart from an outer surface of the lift pin 120 by a certain distance.

The bellows 140 may be coupled to a lower portion of the body 110 and may be configured to move between a vacuum state and an atmospheric state. The vacuum state may include a state in which no air exists and may also include a low pressure state in which air pressure is 1/1000 mmHg or less. In an example embodiment, the bellows 140 may form the lift hole H1 located at the top of the bellows 140 in a vacuum state and form a space adjacent to a load sensor in the atmospheric state. In an example embodiment, the bellows 140 may include an upper flange 141, a lower flange 143, and a flexible pipe 145. The upper flange 141 may be coupled to a lower portion of the body 110 and may be configured to expose the lift hole H1. The lower flange 143 may be disposed to be spaced apart from the upper flange 141 in the vertical direction and may be coupled to the actuator 170. In an example embodiment, the flexible pipe 145 may be an elastic pipe interposed between the upper flange 141 and the lower flange 143 and configured to surround at least a portion of the lift pin 120. The flexible pipe 145 may be configured to be tensioned or compressed according to the movement of the actuator 170. For example, as the actuator 170 moves downwardly, the flexible pipe 145 may be tensioned (e.g., extended), and as the actuator 170 moves upwardly, the flexible pipe 145 may be compressed.

The connection assembly 150 may be coupled to a lower portion of the lift pin 120. In addition, connection assembly 150 may be internal to the bellows 140. More specifically, the connection assembly 150 may be interposed between the lift pin 120 and the piezoelectric resonator 160 within the flexible pipe 145 of the bellows 140. In an example embodiment, the connection assembly 150 may be an assembly configured to interfere with a downward movement of the lift pin 120. However, the connection assembly 150 may be an assembly configured not to interfere with at least any one of rotation based on a first axis extending in a direction parallel to a direction in which the lift pin 120 extends, tilting based on the first axis, and sliding in the plane perpendicular to the first axis. That is, the connection assembly 150 may restrict the downward movement of the lift pin 120, but may allow at least one of the rotation, tilting, and sliding of the lift pin 120. In an example embodiment, the connection assembly 150 may be an assembly configured not to interfere with all of rotation of the lift pin 120 about the first axis, tilting about the first axis, or sliding on a plane perpendicular to the first axis.

The connection assembly 150 may interfere with the downward movement of the lift pin 120, but may not interfere with the rotation, tilting, and sliding of the lift pin 120. In addition, the lift pin 120 may transmit only the load in the vertical direction to the load sensor.

The piezoelectric resonator 160 may be implemented to output a vibration signal to the lift pin 120 or to detect a resonant frequency corresponding to the vibration of the lift pin 120.

A load sensor may be further included at the top and/or bottom of the piezoelectric resonator 160. The load sensor may precisely measure a load applied to the wafer W in the vertical direction. The load sensor may be at the bottom of connection assembly 150. The load sensor may measure the load generated as the lift pin 120 moves in the vertical direction. More specifically, the load sensor may be a sensor accommodating the load generated according to the vertical movement of the lift pin 120 and changing the load into an electrical signal. The load sensor may generate load information according to a vertical displacement of the lift pin 120 and transmit the load information to the controller 180. In an example embodiment, the load sensor may be a load cell including at least one of a strain gauge load cell, a beam load cell, a platform load cell, and a canister load cell. However, the load sensor is not limited thereto and may include various types of sensors capable of changing the load generated according to the vertical movement of the lift pin 120 into an electrical signal.

In an example embodiment, the connection assembly 150 may be configured not to interfere with any of rotation, tilting, or sliding of the lift pin 120. Accordingly, the lift pin 120 may transmit only the vertical load generated according to the vertical movement of the lift pin 120 to the load sensor, and the load sensor may change only the vertical load transmitted from the lift pin 120 into an electrical signal.

The actuator 170 may be located below the bellows 140. More specifically, the actuator 170 may be located below the lower flange 143 of the bellows 140. The actuator 170 may be configured to move the lift pin 120 in the vertical direction. In an example embodiment, the actuator 170 may be moved in the vertical direction by a power member, such as a motor or hydraulic device. The actuator 170 may move the lift pin 120 in substantially the same direction as the movement direction of the actuator 170. In an example embodiment, as the actuator 170 moves up and down, the flexible pipe 145 of the bellows 140 may be tensioned or compressed. For example, when the actuator 170 moves downwardly, the flexible pipe 145 may be tensioned (e.g., extended). In addition, when the actuator 170 moves upwardly, the flexible pipe 145 may be compressed.

The controller 180 may be configured to generally control the vertical movement of the wafer W using the lift device 100. In an example embodiment, the controller 180 may be connected to the load sensor and the actuator 170. The controller 180 may determine the load applied to the wafer W based on the load information generated by the load sensor. For example, when the wafer W that the lift pins 120 move in the vertical direction is a substrate and the controller 180 determines that the load applied to the substrate by the lift pins 120 is excessive, the controller 180 may control the actuator 170 to change the vertical position of the lift pin 120. In an example embodiment, the controller 180 may determine a contact initiation point between the wafer W and the lift pin 120 based on the load information generated by the load sensor. The contact initiation point CP may be defined as a vertical position of the lift pin 120 immediately before the wafer W starts to contact the lift pin 120 and the wafer W is moved upwardly. In an example embodiment, when the wafer W that the lift pin 120 moves in the vertical direction is a moving ring, the controller 180 may determine the contact initiation point CP of the moving ring and the lift pin 120 based on a load size measured by the load sensor.

In addition, the controller 180 may be implemented to detect a resonant frequency from an electrical signal received from the piezoelectric resonator 160 and determine the position of the wafer using the detected resonant frequency. Here, the resonant frequency of the wafer-lift pin structure may change according to the position of the wafer.

In some example embodiments, the controller 180 may be implemented as hardware, firmware, software, or any combinations thereof. For example, the controller 180 may be a computing device, such as a workstation computer, desktop computer, laptop computer, tablet computer, etc. The controller 180 may be a simple controller, a complex processor, such as a microprocessor, a central processing unit (CPU), a graphics processing unit (GPU), or a data processing unit (DPU), a processor configured by software, dedicated hardware, or firmware. The controller 180 may be implemented, for example, by a general-purpose computer or application-specific hardware, such as a digital signal processor (DSP), a field programmable gate array (FPGA), and an application specific integrated circuit (ASIC).

In example embodiments, the operations of controller 180 may be implemented as instructions stored on a machine-readable medium that may be read and executed by one or more processors. Here, machine-readable medium may include any mechanism for storing or transmitting information in a form readable by a machine (e.g., computing device). For example, a machine-readable medium may include read only memory (ROM), random access memory (RAM), magnetic disk storage medium, optical storage medium, flash memory devices, and electrical, optical, acoustic, or other forms of radio signals (e.g., carrier waves, infrared signals, digital signals, etc.) and other arbitrary signals.

The controller 180 may be implemented with firmware, software, routines, and instructions for moving the wafer W in the vertical direction by the lift pin 120. For example, the controller 180 may be implemented by software receiving data for feedback, generating signals for movement of the wafer W by the lift pin 120, and performing predetermined operations.

The lift device 100 of the present inventive concept may measure the load applied to the wafer W in real time and control the lift pins 120 in real time. In addition, the lift device 100 according to an example embodiment of the present inventive concept may precisely measure the position of the wafer in real time through a piezoelectric resonator.

FIG. 9B is a diagram illustrating a lift device 100a according to another example embodiment of the present inventive concept. Referring to FIG. 9B, the lift device 100a may include a body 110, a lift pin 120, a pin guide 130, a bellows 140, a connection assembly 150, a piezoelectric resonator 160, an actuator 170, and a controller 180. As shown in FIG. 9B, the piezoelectric resonator 160 of the lift device 100a may be external to the bellows 140. More specifically, the piezoelectric resonator 160 may be interposed between the lower flange 143 of the bellows 140 and the actuator 170.

FIG. 9C is a diagram illustrating a lift device 100b according to another example embodiment of the present inventive concept. Referring to FIG. 9C, the lift device 100b may include a body 110, a lift pin 120, a pin guide 130, a bellows 140, a connection assembly 150, a piezoelectric resonator 160, an actuator 170, and a controller 180. As shown in FIG. 9C, the lower flange 143 of the bellows 140 of the lift device 100b may include a disposing portion 143a and a deformable portion 143b. In an example embodiment, the disposing portion 143a may be a portion of the lower flange 143 disposed on the actuator 170 and coupled to the flexible pipe 145. In an example, the deformable portion 143b may be a portion of the lower flange 143 coupled to the connection assembly 150 inside the disposing portion 143a. In addition, the deformable portion 143b may include a material that may be deformed by external force and may be physically deformed by the upward and downward movement of the lift pin 120 or the pressure inside the flexible pipe 145. More specifically, when downward external force is applied to the deformable portion 143b due to contact between the wafer W and the lift pin 120, the deformable portion 143b may be bent downwardly. In addition, when the inside of the bellows 140 is formed in a vacuum state, the deformable portion 143b may be bent upwardly.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

In an example embodiment, the load sensor may be coupled to a lower portion of the deformable portion 143b. The load sensor may be configured to measure the load according to the displacement of the lift pin 120 in the vertical direction based on the degree of deformation of the deformable portion 143b and generate load information. As long as the load sensor of the lift device 100b of the present inventive concept may be outside the bellows 140, the load sensor may not be affected by the environment inside the bellows 140 and may be easily managed.

Also, compression resonators and the controller of the present inventive concept may implement an apparatus for detecting a position of a wafer in various combinations.

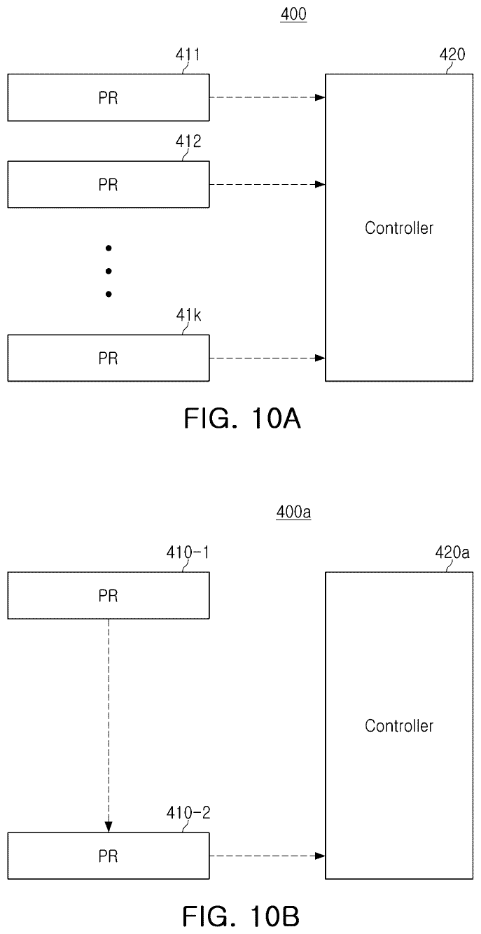

FIGS. 10A and 10B are diagrams illustrating an apparatus for detecting a position of a wafer. Referring to FIG. 10A, the apparatus 400 for detecting a position of a wafer may include a plurality of piezoelectric resonators 411 to 41k (k is an integer of 2 or more) and a controller 420. Each of the plurality of piezoelectric resonators 411 to 41k may be implemented to output a resonant frequency signal according to the vibration of the corresponding lift pin. The controller 420 may be implemented to receive resonant frequency signals from each of the piezoelectric resonators 411 to 41k and determine the position of the wafer using the received resonant frequency signals.

Referring to FIG. 10B, the apparatus 400a for detecting a position of a wafer may include a first piezoelectric resonator 410-1, a second piezoelectric resonator 410-2, and a controller 420a. The first piezoelectric resonator 410-1 may be implemented to output a resonant frequency signal by causing the vibration of the corresponding lift pin. The second piezoelectric resonator 410-2 may be implemented to receive the resonant frequency signal of the first piezoelectric resonator 410-1 and output the resonant frequency signal to the controller 420a. The controller 420a may be implemented to receive the resonant frequency signal from the second piezoelectric resonator 410-2 and determine the position of the wafer using the received resonant frequency signal.

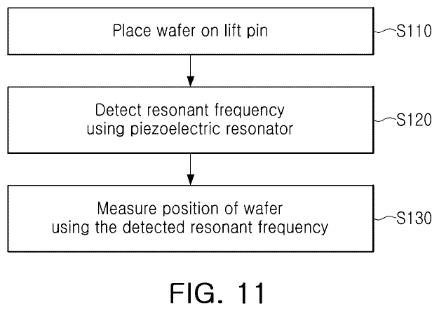

FIG. 11 is a flowchart illustrating a wafer position detection operation of a semiconductor manufacturing apparatus according to an example embodiment of the present inventive concept. Referring to FIGS. 1 to 11, the semiconductor manufacturing apparatus may perform a wafer position detection operation as follows. The wafer may be disposed on the lift pin (S110). The resonant frequency corresponding to the resonance of the lift pin may be detected using a piezoelectric resonator (S120). The position of the wafer may be measured using the detected resonant frequency (S130).

In an example embodiment, the wafer, the lift pins, and the piezoelectric resonator may be implemented as physically independent structures. For example, the piezoelectric resonator may not be integrated with the corresponding lift pin but may instead by physically separable from the corresponding lift pin. In an example embodiment, a number of the piezoelectric resonators may be less than or equal to the number of lift pins. In an example embodiment, the piezoelectric resonator may be implemented below a corresponding lift pin among the lift pins. In an example embodiment, the piezoelectric resonator may be implemented in a connection portion of a corresponding lift pin among the lift pins. For example, the connection portion of the lift pin may connect the lift pin to an element disposed below the lift pin, such as a portion of the bellows 140 or a portion of the actuator 170. In example embodiments, the initial resonant frequency may be detected when the wafer is located in the center of the support stand. In an example embodiment, deviation of the position of the wafer may be determined by comparing the initial resonant frequency to the measured resonant frequency. In example embodiments, the resonant frequency may be lower than the initial resonant frequency when the wafer is off-center of the support stand. In example embodiments, a vibration signal may be generated to vibrate the wafer-lift pin structure. Here, the vibration signal may be generated from a piezoelectric resonator different from the piezoelectric resonator that is used to measure the resonant frequency.

The apparatus for detecting a position of a wafer and its operating method according to an example embodiment of the present inventive concept may detect the position of a wafer in a processing chamber in real time.

The apparatus for detecting a position of a wafer and the operating method thereof according to an example embodiment of the present inventive concept may measure the position of the wafer on the lift pin in real time.

The apparatus for detecting a position of a wafer and the operating method thereof according to an example embodiment of the present inventive concept do not affect the process because the sensor is attached outside the process space.

The apparatus for detecting a position of a wafer and the operating method thereof according to an example embodiment of the present inventive concept may precisely measure the position of the wafer.

The devices described herein may be implemented using hardware components, software components, or a combination thereof. For example, the devices and components described in an embodiment may be implemented using one or more general-purpose or special-purpose computers, such as a processor, a controller, an arithmetic logic unit (ALU), a digital signal processor, a microcomputer, a field programmable gate array (FPGA), a programmable logic unit (PLU), a microcomputer, or any other device capable of executing and responding to instructions. A processing device may be implemented using one or more general-purpose or special purpose computers, such as, for example, a processor, a controller and an arithmetic logic unit, a digital signal processor, a microcomputer, a field programmable gate array, a programmable logic unit, a microprocessor or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is used as singular; however, one skilled in the art will appreciated that a processing device may include multiple processing elements and multiple types of processing elements. For example, a processing device may include multiple processors or a processor and a controller. In addition, different processing configurations are possible, such a parallel processors.

The software may include a computer program, a piece of code, an instruction, or some combination thereof, to independently or collectively instruct or configure the processing device to operate as desired. Software and data may be embodied permanently or temporarily in any type of machine, component, physical or virtual equipment, computer storage medium or device, or in a propagated signal wave capable of providing instructions or data to or being interpreted by the processing device. The software also may be distributed over network coupled computer systems so that the software is stored and executed in a distributed fashion. The software and data may be stored by one or more non-transitory computer readable recording mediums.

A wafer position detection device according to an embodiment of the present invention may detect the degree of positional misalignment by changes in the resonant frequency corresponding to the wafer position. In an embodiment, a piezoelectric resonator may be used that matches the resonant frequency range of the structure. In an embodiment, the spring constant value of the structure and the resonant frequency range may be determined by the length, width, and material specifications of the lift pin. In an embodiment, the wafer, lift pin, and piezoelectric resonator may have physically independent structures. In an embodiment, at least one resonator may be used and a number of the resonators up to the number of pins may be used. In an embodiment, the frequency measuring resonator may be implemented in a structure applied to the lower end of the lift pin or the connection part of the lift pin. The wafer position detection device and the operating method may detect the position of a wafer in real-time within a process chamber. The wafer position detection device and the operating method may measure the position of the wafer on a lift pin in real-time. The wafer position detection device and the operating method do not affect the process as the sensor is attached outside the process space. The wafer position detection device and the operating method may precisely measure the position of the wafer.

While example embodiments have been shown and described above, it will be apparent to those skilled in the art that modifications and variations could be made without departing from the scope of the present inventive concept.

What is claimed is:

1. An apparatus for detecting a position of a wafer, the apparatus comprising:
a plurality of lift pins configured to seat the wafer on a support stand; and
a plurality of piezoelectric resonators at lower portions of the plurality of lift pins, respectively,
wherein at least one first piezoelectric resonator among the plurality of piezoelectric resonators is configured to vibrate a corresponding lift pin of the plurality of lift pins,
wherein at least one second piezoelectric resonator among the plurality of piezoelectric resonators is configured to detect a resonant frequency of a combined structure including the wafer and the plurality of lift pins, the resonant frequency corresponding to the vibration, and
wherein the apparatus further comprises a controller configured to determine the position of the wafer according to a change in the resonant frequency.

2. The apparatus of claim 1, wherein each of the plurality of lift pins is configured to move vertically through the support stand.

3. The apparatus of claim 1, wherein the at least one first piezoelectric resonator is configured to generate a vibration signal in a predetermined frequency range.

4. The apparatus of claim 3, wherein the at least one second piezoelectric resonator is configured to detect the resonant frequency by converting the vibration signal into an electrical signal.

5. The apparatus of claim 1, wherein
the at least one second piezoelectric resonator is configured to output an electrical signal corresponding to the resonant frequency, and
the controller is configured to receive the electrical signal and determine the position of the wafer according to the received electrical signal.

6. The apparatus of claim 5, wherein the controller is configured to measure the change in the resonant frequency corresponding to a change in a spring constant of the combined structure.

7. The apparatus of claim 6, wherein a first spring constant corresponding to the wafer being at a central position of the support stand is greater than a second spring constant corresponding to the wafer being off-center.

8. The apparatus of claim 1, wherein the resonant frequency decreases as the wafer is positioned further from a center of the support stand.

9. The apparatus of claim 1, wherein the resonant frequency varies according to a length, width, or material of each of the plurality of lift pins.

10. The apparatus of claim 1, wherein each of the plurality of piezoelectric resonators is physically separable from the corresponding lift pin.

11. An apparatus for detecting a position of a wafer, the apparatus comprising:
a plurality of piezoelectric resonators; and
a controller configured to receive an electrical signal, the electrical signal corresponding to a resonant frequency of a combined structure including the wafer and a plurality of lift pins, from at least one of the plurality of piezoelectric resonators and determine the position of the wafer according to the received electrical signal.

12. The apparatus of claim 11, wherein each of the plurality of piezoelectric resonators is positioned at a lower portion of a corresponding lift pin of the plurality of lift pins.

13. The apparatus of claim 11, wherein each of the plurality of piezoelectric resonators is positioned at a connection portion of a corresponding lift pin of the plurality of lift pins.

14. The apparatus of claim 11, wherein at least one of the plurality of piezoelectric resonators is configured to generate a vibration signal.

15. The apparatus of claim 14, wherein the remainder of the plurality of piezoelectric resonators are configured to generate the electrical signal corresponding to the resonant frequency by detecting the vibration signal.

16. An apparatus for detecting a position of a wafer, the apparatus comprising:
a lift pin configured to move vertically within a hole of a support stand to seat the wafer on the support stand;
a connector connected to a lower portion of the lift pin;
a piezoelectric resonator at a lower portion of the connector, the piezoelectric resonator being configured to detect a resonant frequency of the lift pin;
an actuator configured to move the lift pin vertically; and
a controller configured to control the actuator,
wherein the controller is configured to receive an electrical signal corresponding to the resonant frequency from the piezoelectric resonator and determine the position of the wafer according to the electrical signal.

17. The apparatus of claim 16, wherein a range of the resonant frequency is determined according to a length, thickness, or material of the lift pin.

18. The apparatus of claim 16, wherein the controller is configured to control the piezoelectric resonator to generate a vibration signal.

19. The apparatus of claim 16, wherein the resonant frequency changes according to the position of the wafer.

20. The apparatus of claim 16, wherein a resonant frequency when the wafer is located at a center of the support stand and a resonant frequency when the wafer deviates from the center of the support stand are different from each other.

21-30. (canceled)
